(19) United States
(12) Patent Application Publication
(10) Pub. No.: US 2025/0285836 A1
(43) Pub. Date: Sep. 11, 2025

(54) PLASMA DEPOSITION APPARATUS AND PLASMA DEPOSITION METHOD

(71) Applicant: Samsung Electronics Co., Ltd., Suwon-si (KR)

(72) Inventors: Sangchul Han, Suwon-si (KR); Doyoung Kim, Suwon-si (KR); Yihwan Kim, Suwon-si (KR); Youngbok Lee, Suwon-si (KR); Junho Lee, Suwon-si (KR); Daegyu Lim, Suwon-si (KR); Seokjun Hong, Suwon-si (KR); Jongyong Park, Suwon-si (KR); Sungjun Ann, Suwon-si (KR); Seungkyu Lim, Suwon-si (KR); Jinwoong Cho, Suwon-si (KR)

(21) Appl. No.: 18/909,746

(22) Filed: Oct. 8, 2024

(30) Foreign Application Priority Data
Mar. 11, 2024 (KR) 10-2024-0033763

(51) Int. Cl. H01J 37/32; H01J 37/34

(52) U.S. Cl. CPC H01J 37/32128; H01J 37/32834; H01J 37/3497

(57) ABSTRACT

A plasma deposition apparatus includes a process chamber; a substrate stage including an electrostatic chuck, a lower temperature maintenance portion and a lower electrode, in which the electrostatic chuck is configured to hold a substrate using an electrostatic adsorption force, and the low temperature maintaining portion is configured to cool the substrate; an exhaust portion configured to exhaust a gas inside the process chamber; an upper electrode disposed on an upper portion of the process chamber facing the lower electrode; a gas supply portion configured to supply a reaction gas into the process chamber, a first power supply configured to generate plasma; and a second power supply configured to control an ion energy of the plasma.

### CROSS-REFERENCE TO RELATED APPLICATIONS

This application claims priority under 35 U.S.C. § 119 to Korean Patent Application No. 10-2024-0033763, filed on Mar. 11, 2024, in the Korean Intellectual Property Office (KIPO), the disclosure of which is herein incorporated by reference in its entirety.

### BACKGROUND

In a related manufacture of a semiconductor, a carbon hard mask may be used as a mask for an exposure process. In order to obtain a hard mask having a relatively higher strength, a process having a relatively high temperature process condition may be used, but there are various hardware limitations. Thus, in order to improve the layer quality, a method of depositing a hard mask under low-temperature process conditions may be introduced, and accordingly equipment using a capacitive coupled plasma (CCP) type sinusoidal RF plasma power source may be used under low-temperature process conditions. However, when using a single sinusoidal RF plasma power source, the ion flux (ion density) and ion energy cannot be controlled independently, and the ion energy band width of sinusoidal bias is wide, making it difficult to obtain a high-quality carbon hard mask layer with a high selectivity.

### SUMMARY

In general, in some aspects, the present disclosure is directed toward a plasma deposition apparatus capable of independently controlling density and energy of plasma ion and a carbon hard mask deposition method using the plasma deposition apparatus.

According to some implementations, the present disclosure is directed to a plasma deposition apparatus that includes a process chamber; a substrate stage including an electrostatic chuck, a lower temperature maintenance portion and a lower electrode, wherein the electrostatic chuck is configured to hold a substrate thereon with an electrostatic adsorption force, and the low temperature maintaining portion is configured to cool the substrate; an exhaust portion including a vacuum pump that is configured to exhaust a gas inside the process chamber; an upper electrode disposed on an upper portion of the process chamber to face the lower electrode; a gas supply portion configured to supply a reaction gas including a hydrocarbon compound gas into the process chamber, a first power supply configured to apply a source voltage of a sinusoidal waveform to the upper electrode to generate plasma; and a second power supply configured to apply a bias voltage of a non-sinusoidal waveform to the lower electrode to control an ion energy of the plasma.

According to some implementations, the present disclosure is directed to a plasma deposition apparatus that includes a chamber configured to provide a space for processing a substrate, a substrate stage configured to support the substrate, the substrate stage having a lower electrode, an upper electrode disposed to face the lower electrode, a first power supply having a sinusoidal power source that is configured to apply a sinusoidal voltage signal to the upper electrode to generate plasma inside a plasma region of the chamber, a second power supply configured to apply a non-sinusoidal voltage signal to the lower electrode to control an ion energy of the plasma, a gas supply portion configured to supply a reaction gas into the plasma region, an exhaust portion having a vacuum pump that is configure to exhaust a gas inside the process chamber, a substrate temperature adjustment portion configured to maintain a temperature of the substrate below a preset temperature. The reaction gas includes a hydrocarbon compound selected from the group consisting of C₃H₆, C₄H₈, C₆H₁₂, and CH₄ to deposit a carbon layer from the reaction gas.

According to some implementations, the present disclosure is directed to a plasma deposition apparatus that includes a chamber configured to provide a space for processing a substrate, a substrate stage configured to support the substrate therein, the substrate stage having a lower electrode, an upper electrode disposed to face the lower electrode, a gas supply portion configured to supply a reaction gas including hydrocarbon compound gas into the plasma region, a first power supply having a sinusoidal power source that is configured to apply a sinusoidal voltage power to the upper electrode to generate plasma inside the chamber, a second power supply having a non-sinusoidal power source that is configured to apply a non-sinusoidal voltage power to the lower electrode to form a carbon layer on the substrate. The non-sinusoidal power has a voltage waveform that is repeated at a preset period. The preset period includes a pulse period where the non-sinusoidal power having a fixed voltage level higher than a reference voltage level is applied and a ramp period where the non-sinusoidal power having a variable voltage level that decreases at a constant slope from a first voltage level lower than the reference voltage level to a second voltage level lower than the first voltage level is applied.

According to some implementations, the present disclosure is directed to a method of manufacturing a carbon hard mask, in which a substrate is loaded onto a lower electrode of a process chamber that has an upper electrode and the lower electrode. A temperature of the substrate is set to a preset temperature range. A pressure of the process chamber to a preset pressure range is set. A processing gas is injected gas into the process chamber and a source voltage signal is applied on the upper electrode to generate plasma inside the process chamber. A reaction gas including hydrocarbon compound gas is injected into the process chamber and the reaction gas is collided with the plasma to form an activated reaction gas. A non-sinusoidal bias voltage signal is applied to the lower electrode to deposit a carbon layer on the substrate from the activated reaction gas.

According to some implementations, the present disclosure is directed to a plasma deposition apparatus that may include a process chamber, a substrate stage having an electrostatic chuck that is configured to hold a substrate with an electrostatic adsorption force thereon, the substrate stage having a low temperature maintenance portion configured to cool the substrate, the substrate stage having a lower electrode, an exhaust portion having a vacuum pump that is configured to exhaust a gas inside the process chamber, an upper electrode disposed in an upper portion of the process chamber to face the lower electrode, a gas supply portion configured to supply a reaction gas including a hydrocarbon compound gas into the process chamber, a first power supply configured to apply a source voltage of a sinusoidal waveform to the upper electrode to generate plasma, and a second power supply configured to apply a bias voltage of a non-sinusoidal waveform to the lower electrode to control an ion energy of the plasma.

According to some implementations, the present disclosure is directed to a carbon hard mask that may be deposited using inductively coupled plasma ICP under low-temperature conditions. A sinusoidal power applied to the upper electrode may control a density of plasma ions, and a non-sinusoidal power applied to the lower electrode may control an energy of the plasma ions by inducing a DC-type voltage to the substrate. That is, by providing a decoupled plasma source capable of independently controlling the density of plasma ions and an energy width of the plasma ions to have an optimal plasma ion density and energy, it may be possible to manufacture a diamond-like carbon hard mask having a high selectivity.

### BRIEF DESCRIPTION OF THE DRAWINGS

Example implementations will be more clearly understood from the following detailed description, taken in conjunction with the accompanying drawings.

FIG. 1 is a cross-sectional view illustrating an example of a plasma deposition apparatus in accordance with some implementations.

FIG. 2 is a graph illustrating an example of an ion energy distribution of ions in plasma generated when a power signal having a sinusoidal voltage is supplied to a lower electrode, wherein no upper electrode is provided, in accordance with some implementations.

FIG. 3 is a graph illustrating an example of an ion energy distribution of ion in plasma in accordance with some implementations.

FIG. 4 is a view illustrating an example of an electrical connection relationship between a lower electrode and a substrate of FIG. 1 in accordance with some implementations.

FIG. 5 is a graph illustrating an example of a bias voltage signal having a non-sinusoidal waveform applied by a second power supply in accordance with some implementations.

FIG. 6 is a graph illustrating an example of an induce voltage induced on a substrate by a bias voltage signal of FIG. 5 over time in accordance with some implementations.

FIG. 7 is a process flowchart illustrating an example of a method of manufacturing a carbon mask using the plasma deposition apparatus illustrated in FIG. 1 in accordance with some implementations.

### DETAILED DESCRIPTION

Hereinafter, example implementations will be explained in detail with reference to the accompanying drawings.

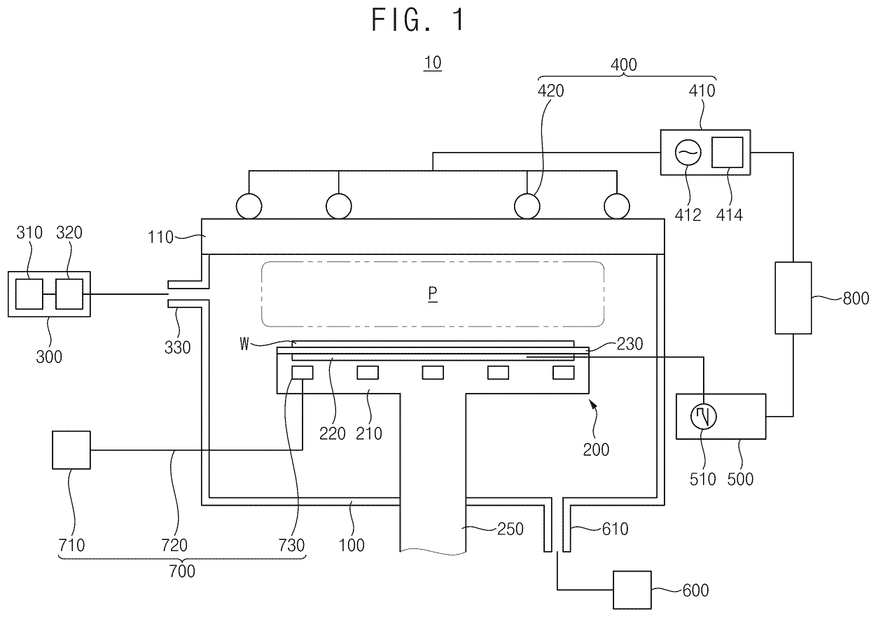

FIG. 1 is a cross-sectional view illustrating an example of a plasma deposition apparatus in accordance with some implementations. In FIG. 1, a plasma deposition apparatus 10 may include a process chamber 100, a substrate stage 200 having a lower electrode 220 and configured to support a substrate, a gas supply portion 300, a plasma generation portion 400 configured to form plasma within the process chamber 100, and a plasma energy adjustment portion 500 configured to apply a bias power to the lower electrode 220 to control an ion energy of the plasma. Additionally, the plasma deposition apparatus 10 may further include an exhaust portion 600 and a substrate temperature adjustment portion 700.

In some implementations, the plasma deposition apparatus 10 may include an inductively coupled plasma (ICP) chamber. The plasma deposition apparatus 10 may be an apparatus configured to form a layer on a substrate, such as a semiconductor wafer, disposed inside the ICP chamber. Here, the substrate may include a semiconductor substrate, a glass substrate, etc. However, the plasma generated by the plasma deposition apparatus is not limited to the inductively coupled plasma, and may be, for example, a microwave type plasma.

The ICP plasma generation portion 40 of the plasma deposition apparatus 10 may include a coil outside the process chamber 100 and may change an electric field applied to the coil to generate plasma by using a secondary induced current formed in the process chamber by an induced magnetic field induced in the coil. The gas supply portion 300 may supply a reactive gas into the process chamber and the reactive gas may be decomposed by the plasma to deposit a thin layer. In some implementations, the deposition apparatus may be provided as a plasma enhanced chemical vapor deposition (PECVD) apparatus.

In some implementations, a microwave-type plasma generation portion of the plasma deposition apparatus 10 may include a radial line slot antenna. The plasma generation portion may use microwaves radiated from the slot antenna to excite the plasma. The microwave-type plasma generation portion may introduce microwaves into the process chamber 100 through a dielectric window in an upper portion of the process chamber 100. A high-density plasma may be excited by the microwave in a region under the dielectric window.

The process chamber 100 may provide a sealed space where a plasma process is performed on the substrate W. The process chamber 100 may be a cylindrical vacuum chamber. The process chamber 100 may include a metal such as aluminum, stainless steel, etc. A gate for loading/unloading the substrate W may be installed in a sidewall of the process chamber 100. The substrate W may be loaded/unloaded onto/from the substrate stage through the gate.

The substrate stage 200 may include a disk-shaped lower electrode 220 in the electrostatic chuck 210. The lower electrode 220 may be disposed to be vertically movable by a driving portion 250.

The substrate stage 200 may include a support plate 230 having an electrostatic electrode thereon for holding the substrate W using electrostatic force. The electrostatic electrode may adsorb and maintain the substrate W with the electrostatic force when a direct current is applied thereto by a direct current power source via a switch (not illustrated) which is turned on/off. The substrate W may be disposed on a dielectric layer 240 on the support plate 230 of the substrate stage 200.

The gas supply portion 300 may include a gas supply source 310, a flow rate controller 320, and a gas supply line 330 as gas supply elements. The gas supply line 330 may be connected to the process chamber 100, and the flow rate controller 320 may control a supply flow rate of a gas supplied into the process chamber 100 through the gas supply line 330. For example, the gas supply source 310 may include a plurality of gas tanks, and the flow rate controller 320 may include a plurality of mass flow controllers (MFC) corresponding to the gas tanks, e.g., respectively connected to the gas tanks. The mass flow rate controllers may independently control the supply flow rates of the gases.

The gas supply portion may supply different process gases into the process chamber 100. For example, the process gases may include inert gases or hydrocarbon compound gases. The gas supply portion may provide a process gas for generating plasma in the process chamber 100. Examples of the process gas for generating the plasma may be an inert gas, such as helium (He) gas, argon (Ar) gas, etc. The gas supply portion may provide a process gas for forming a carbon hard mask layer. The process gas for depositing the carbon hard mask layer may include a hydrocarbon compound gas. The hydrocarbon compound gas may include hydrocarbon compounds, such as C₃H₆, C₄H₈, C₆H₁₂, CH₄, etc.

The exhaust portion 600 may be connected to an exhaust port 610 that is provided in a bottom portion of the process chamber 100 through an exhaust line. The exhaust portion 600 may include a vacuum pump, such as a turbo molecular pump, to control a pressure of the process chamber 100 so that the processing space may be depressurized to a desired/proper/predetermined vacuum degree. For example, the vacuum pump may maintain a pressure inside the process chamber under 10 mTorr or less. Additionally, process by-products and residual process gases generated in the process chamber 100 may be discharged through the exhaust port 610.

The substrate temperature adjustment portion 700 may include a low-temperature maintenance portion 710, a refrigerant supply pipe 720, and a cooling channel 730, such as temperature control elements that are configured to maintain a temperature of the substrate W on the substrate stage 200 within a predetermined range. The low-temperature maintenance portion 710 may provide a refrigerant to the cooling channel 730 provided in a lower portion of the lower electrode 220 in the substrate stage 200 through the refrigerant supply pipe 720. The cooling channel 730 may be provided as paths through which the refrigerant gas circulates. For example, the refrigerant gas may include low-temperature helium (He) gas. The cooling channel may be formed in a spiral shape inside the substrate stage 200. The refrigerant may control the substrate W to a constant temperature while flowing through the cooling channel 730. For example, a temperature of the substrate W may be maintained within a range of −10° C. to 130° C. The low-temperature maintenance portion 710 may control the temperature of the substrate W by controlling a flow rate of the refrigerant.

The ICP plasma generation portion may include an upper electrode 420 that is disposed on an upper portion of the process chamber 100 to face the lower electrode 220. The upper electrode 420 may be disposed on an insulating plate 110 in an upper wall of the process chamber 100 outside the process chamber 100. The upper electrode 420 may include a high frequency (RF) antenna. The antenna may have a planar coil shape. An electromagnetic field induced by the high frequency antenna may be applied to the process gas injected into the process chamber 100 to form plasma. A chamber space between the upper electrode 420 and the lower electrode 220 may be used as a plasma generation region.

The ICP plasma generation portion may include a first power source 410 as a plasma source power supply that applies a plasma power having a sinusoidal waveform to the upper electrode 420. The first power source 410 may apply the plasma power to the upper electrode 420 to form plasma P inside the process chamber 100.

For example, the first power source 410 as a plasma source may include a radio frequency (RF) power source 412 and an RF matcher 414 as plasma source elements. The RF power source 412 may generate an RF signal (or a high frequency signal). The first power source 410 may apply an RF power signal (i.e., plasma power) to the upper electrode 420 in response to a plasma power control signal from a controller 800. For example, the RF power signal may be generated as RF power having a frequency range of about 13 MHz to 2.45 GHz and an RF power range of about 50 W to 3,000 W. The RF matcher 414 may match impedance of the RF power signal generated by the RF power source 412 to control plasma P generated by using coils. The first power source 410 may control a density of the plasma P by controlling the frequency and power of the RF power signal.

For example, when a RF power signal with a frequency of 13.56 MHz is applied to the upper electrode 420, the electric field applied to the coil is changed, and the secondary induced current by the induced magnetic field inside the coil may be applied to the process gas inside the process chamber to generate plasma.

The plasma energy adjustment portion 500 may include a second power source 510 as an energy adjustment bias power supply that applies a bias power having a non-sinusoidal waveform to the lower electrode 220. The second power source 510 may control an ion energy of the plasma P in the process chamber 100 by applying the bias power to the lower electrode 220. The second power source 510 may apply the bias power to the lower electrode 220 to adjust the plasma energy so as to have a narrow energy width, and may serve to accelerate a reaction gas that is ionized by colliding with the plasmaized particles toward the substrate W.

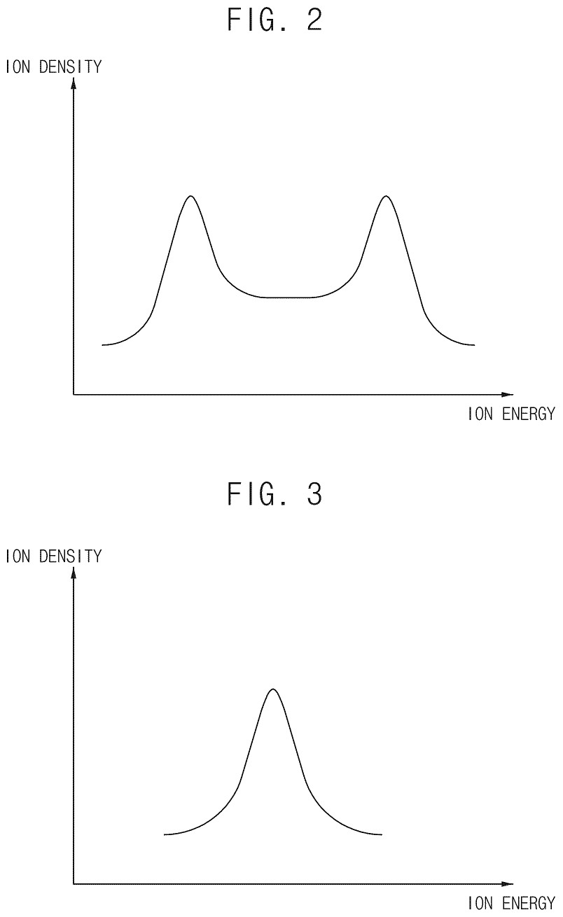

FIG. 2 is a graph illustrating an example of an ion energy distribution of ions in plasma generated when a power signal having a sinusoidal voltage waveform is supplied to a lower electrode, wherein no upper electrode is provided, in accordance with some implementations. In FIG. 2, an ion energy distribution of ions in plasma having a bi-peak type distribution, in which two peaks exist may be obtained by applying a power signal having a sinusoidal voltage waveform, wherein no upper electrode is provided in a plasma deposition apparatus. When a material layer is formed using ions corresponding to one of the two peaks, a material layer, a structure, etc. on a substrate may be damaged by ions corresponding to the other peak.

FIG. 3 is a graph illustrating an example of an ion energy distribution of ion in plasma in accordance with some implementations. In FIG. 3, an ion energy distribution of a single peak shape may be obtained by applying a bias voltage signal of a non-sinusoidal waveform to a lower electrode and applying a plasma voltage signal to an upper electrode. Accordingly, it may be possible to have an optimal energy distribution when depositing a material layer, and the material properties of the material layer including density and strength may be improved compared to the energy distribution having the bi-peak distribution.

In some implementations, a size and position of a peak (i.e., a single peak) in the ion energy distribution may have a relationship with a specific parameter of the non-sinusoidal wave, and the position and size of the single peak may be adjusted by changing the specific parameters. For example, as will be described below in FIG. 5, a height of a fixed voltage level VF of a pulse portion S, a voltage difference (i.e., first voltage delta dV) between the fixed voltage level VF of the pulse portion S and a first voltage level VI of a lamp portion R, a slope of the ramp portion R, etc. may be adjusted to adjust the position and size of the single peak. However, the parameters of the non-sinusoidal wave for adjusting the position and size of the single peak may not be limited thereto.

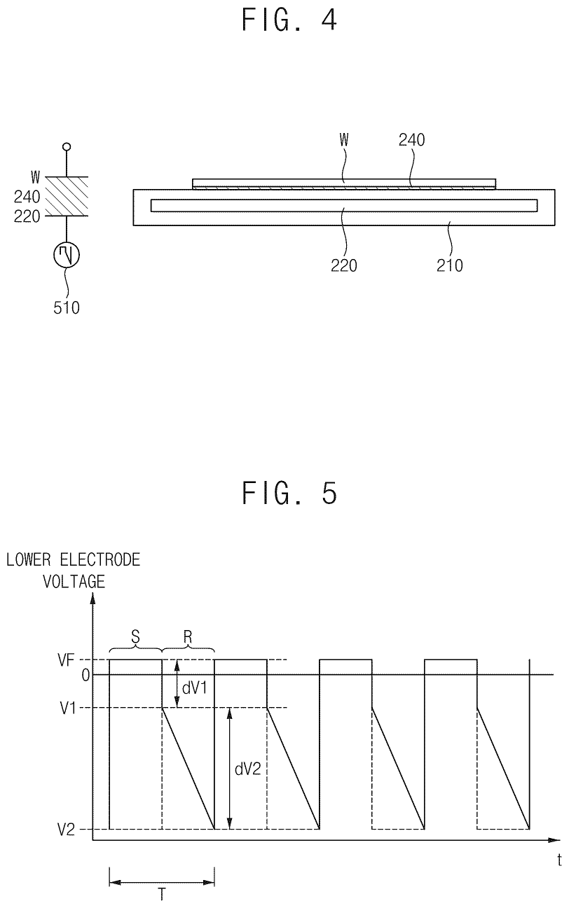

FIG. 4 is a view illustrating an example of an electrical connection relationship between a lower electrode and a substrate of FIG. 1 in accordance with some implementations. In FIG. 4, a dielectric layer 240 may be positioned on an upper surface of the electrostatic chuck 210. A substrate W may be disposed on the dielectric layer 240. As power is applied to the lower electrode 220 inside the electrostatic chuck 210, the substrate W, the dielectric layer 240, and the lower electrode 220 may form a capacitor circuit. Accordingly, an induced voltage may be generated in the substrate W by the power applied to the lower electrode.

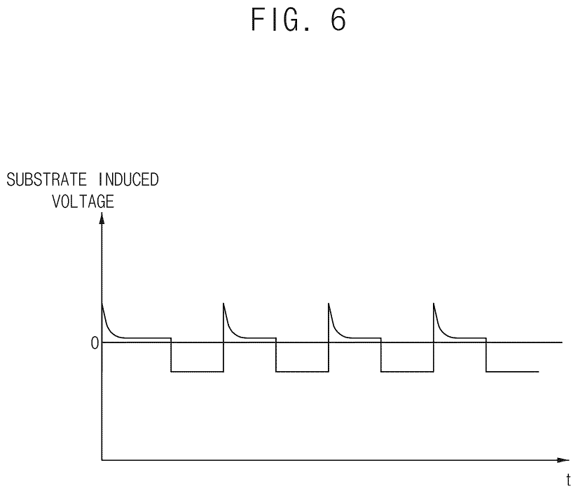

FIG. 5 is a graph illustrating an example of a bias voltage signal having a non-sinusoidal waveform applied by a second power supply in accordance with some implementations. FIG. 6 is a graph illustrating an example of an induce voltage induced on a substrate by the bias voltage signal of FIG. 5 over time in accordance with some implementations.

In FIGS. 5 and 6, the second power source 510 may apply a bias voltage signal having a non-sinusoidal waveform to the lower electrode 220 to generate an induced voltage to the substrate W. The bias voltage signal may have a same type of waveforms that are repeated at a constant period T. One period T of the bias voltage signal may include a pulse portion S and a ramp portion R. However, it is not limited thereto, and the non-sinusoidal waveform may have different waveforms repeated at a constant period.

The pulse portion S may apply a positive (+) voltage to the lower electrode 220. For example, the pulse portion S may maintain a voltage level as a voltage of a fixed voltage level VF.

The ramp portion R may have a graph having a negative slope that decreases from a first voltage level V1 having a negative (−) voltage value to a second voltage level V2. The first voltage level VI may have a voltage difference of a first voltage delta dV1 with the fixed voltage level VF. The value of the first voltage delta may be adjustable, and the ion energy of the plasma ions may be adjusted by adjusting the value of the first voltage delta. For example, the value of the first voltage delta dV1 may be 400 V or more.

The ramp portion R may have a negative slope that decreases from the first voltage level V1 to the second voltage level V2. The bias voltage having the negative slope may induce a voltage on the substrate W to generate a substrate-induced voltage. For example, as illustrated in FIG. 6, a voltage having a constant value similar to a DC voltage may be induced on the substrate in a period corresponding to the period of the ramp portion R. By adjusting a slope of the negative slope, the substrate-induced voltage may have a constant value and the surface of the substrate W may be prevented from being charged by plasma positive ions.

The first voltage level VI and the second voltage level V2 may have a voltage difference of a second voltage delta dV2. The second voltage delta dV2 may be adjusted by the negative slope and a length (duration) of the ramp portion. For example, the second voltage delta dV2 may be adjusted to be 100V or more. The ion energy distribution on the surface of the substrate W may be controlled by adjusting the second voltage delta.

In some implementations, as illustrated in FIG. 6, the ratio of lengths (time ratio) of the pulse portion S and the ramp portion R in the bias voltage signal, that is, a duration ratio of the ramp portion R in one cycle of the bias power signal may be adjusted. For example, the duration ratio of the ramp portion R within one period may be adjusted while the slope of the ramp portion R is maintained to have a constant value. For example, the duration ratio of the ramp portion R may be within a range of about 40% to 80% of one period T.

A plasma voltage signal applied by the first power source and a bias voltage signal applied by the second power source may be variably adjusted, respectively. For this purpose, the controller 800 may be connected to the first power source 410 and the second power source 510 to control their operations. The control portion may include a microcomputer and various interfaces, and may control an operation of the plasma processing apparatus based on programs and recipe information stored in an external memory or an internal memory.

According to some implementations, the deposition apparatus using inductively coupled plasma (ICP) may form a carbon layer at a high deposition rate due to a high plasma density, and may form an ion energy distribution of a single peak using bias power of a non-sinusoidal waveform, and may independently control plasma ion density and energy to apply appropriate ion bombardment energy to control the crystallinity of a thin layer. Accordingly, a carbon mask having a higher selectivity than the related art may be formed.

Hereinafter, a method of manufacturing a carbon mask layer on a substrate W using the plasma deposition apparatus 10 of FIG. 1 will be described.

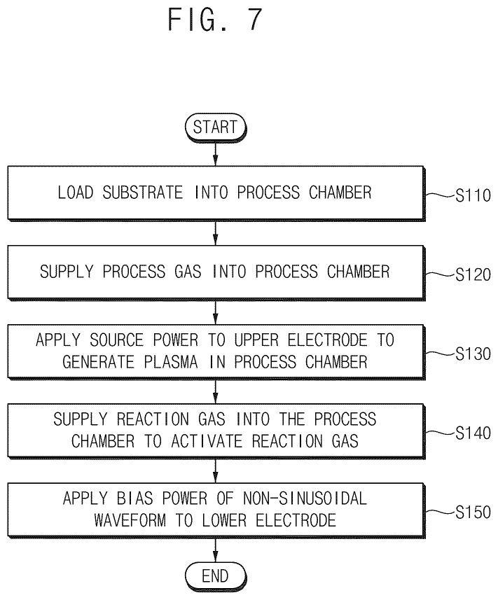

FIG. 7 is a process flowchart illustrating an example of a method of manufacturing a carbon mask using the plasma deposition apparatus illustrated in FIG. 1 in accordance with some implementations. In FIG. 7, first, a substrate W on which a deposition process is to be performed may be loaded into a process chamber 100 (S110).

In some implementations, first, the substrate W may be loaded onto an electrostatic chuck 210 that is provided in a lower portion of the process chamber 100 and has a lower electrode 220 disposed therein. In this case, a pressure of the process chamber 100 may be maintained at a pressure of 10 mTorr or less by an exhaust portion 600.

Then, a temperature of the substrate W may be maintained low through a low-temperature maintenance portion 710 that supplies a low-temperature refrigerant gas to a bottom surface of the lower electrode 220 inside the electrostatic chuck 210. For example, the temperature of the substrate W may be maintained at a temperature within a range of about −10° C. to about 130° C. The refrigerant gas may include helium gas (He). By maintaining the temperature of the substrate W at a relatively low temperature, the transparency of the obtained carbon-based hard mask layer may be improved.

Then, a process gas for generating plasma may be supplied into the process chamber 100 (S120).

Examples of the process gas for generating the plasma may be an inert gas, such as helium (He) gas and argon (Ar) gas. The process gas may be injected into the process chamber through a gas supply portion 300. Since an inside of the process chamber 100 is maintained at a low pressure of 10 mTorr or less, the process gas may be uniformly diffused into an inner space of the process chamber 100.

Then, source power may be applied to the process gas to generate plasma from the process gas (S130).

When the first power source 410 connected to the upper electrode 420 may apply the source power to the process gas introduced into the process chamber 100, ions in a plasma state may be generated from the process gas. In this case, the ions generated in the plasma state may include positively (+) charged particles, negatively (−) charged particles, and electrons. The source power may be generated as an RF voltage signal having a frequency within a range of about 13 MHz to 2.45 GHz and an RF power within a range of about 50 W to 3,000 W. The first power source 410 may control a density of the plasma P generated by controlling frequency and power.

Then, a reaction gas that may be activated by reaction with the plasma to be deposited in a form of a carbon layer may be supplied into the process chamber 100 (S140).

In some implementations, the reaction gas may include a hydrocarbon compound gas, such as C₃H₆, C₄H₈, C₆H₁₂, and CH₄. When the hydrocarbon compound gas is introduced, the ions generated in the plasma state may be collided with the hydrocarbon compound gas, so that ionized carbon particles may be intensively generated. When the hydrocarbon compound gas is out of a preset input flow rate range, it may not be evenly sprayed onto the substrate W and a carbon layer with a uniform thickness may not be formed. Accordingly, a flow rate controller 320 may control a flow rate of the hydrocarbon compound gas.

Then, bias power of a non-sinusoidal waveform may be applied to the substrate W to direct the activated reaction gas toward the substrate W (S150).

The bias power may be applied to the substrate W by a second power source 510 connected to the lower electrode 220. By applying the bias power after an application of the source power is stopped, the ionized carbon particles may be directed toward the substrate W by the bias power.

The second power source 510 may apply the bias power having the non-sinusoidal waveform to the lower electrode 220 to generate an induced voltage to the substrate W. The bias power may have a voltage signal having a shape in which a waveform repeats in a predetermined period with same wave shape. The predetermined period of the bias voltage signal may include a pulse portion S and a ramp portion R.

The pulse portion S may apply a positive voltage to the lower electrode 220. For example, the pulse portion S may maintain a voltage level as a fixed bias voltage signal with a voltage of the fixed voltage level VF. The ramp portion R may have a graph having a negative slope that decreases from a first voltage level VI having a negative (−) voltage value to a second voltage level V2. The first voltage level VI may have a voltage difference of a first voltage delta dV1 with the fixed voltage level VF. The value of the first voltage delta dV1 may be adjustable, and ion energy of plasma ions may be controlled by adjusting the value of the first voltage delta dV1. For example, the first voltage delta dV1 may have a value of 400V or more.

The ramp portion R may have a negative slope that decreases from the first voltage level V1 to the second voltage level V2. The bias voltage having the negative slope may induce a voltage in the substrate W to induce a voltage having a constant value similar to the DC voltage in a section corresponding to the section of the ramp portion R in the substrate W. By adjusting the negative slope, the substrate induction voltage may have a constant value and the surface of the substrate W may be prevented from being charged by the plasma positive ions.

The first voltage level V1 and the second voltage level V2 may have a voltage difference of a second voltage delta dV2. The second voltage delta dV2 may be adjusted by a slope of the negative slope and a length of the ramp portion. For example, the second voltage delta dV2 may be adjusted to be 100V or more. Ion energy distribution on a surface of the substrate W may be controlled by adjusting the second voltage delta.

In some implementations, a ratio of the lengths of the pulse portion S and the ramp portion R in the bias voltage signal, that is, a time ratio of the ramp portion R in one period of the bias voltage signal may be adjusted. For example, a ratio of the ramp portion R may be adjusted while the slope of the ramp portion R is maintained to have a constant value. For example, the ratio of the ramp portion R may be within a range of about 40% to 80% of one period.

By controlling the bias voltage signal, the ionized carbon particles may form a diamond-like carbon layer that has a three-dimensional bonding structure of a regular tetrahedron such as diamond as a dominant structure on the substrate W, compared to a two-dimensional structure of graphite. In this case, the diamond-like carbon layer may have a sp3hybrid structure, and the sp3 hybrid structure may increase not only hardness of the diamond-like carbon layer but also transparency of the diamond-like carbon layer as compared with the sp2 hybrid structure. Accordingly, the diamond-like carbon layer formed on the substrate W may have high transmittance, and may have high etch selectivity when used as a hard mask layer due to high carbon density.

When the density of the diamond-like carbon layer increases, it may be provided as an excellent hard mask layer having high selectivity. However, when the layer density increases, the layer stress may increase, and the diamond-like carbon layer may be peeled off or bent from the substrate. The diamond-like carbon layer in accordance with example embodiments may be formed to have a density of 2.0 g/cc or more. The diamond-like carbon layer may be formed to have a layer stress of 1 GPa or less.

A source power and a bias power may be appropriately controlled to improve a crystallinity and a carbon density of the diamond-like carbon layer to thereby form the carbon-hard mask layer having a high etch selectivity. When a deposition process of the diamond-like carbon layer is completed on the substrate W, injection of the reactive gas used in the deposition process may be blocked.

After turning off the bias power, pumping the process gas and reaction residue inside the process chamber 100 to the outside of the process chamber 100 to form a vacuum, substrate W on which the deposition process is completed may be unloaded from the process chamber 100.

As described above, according to some implementations, the carbon hard mask may be manufactured using the plasma deposition apparatus. It may be possible to control the density of plasma ions by supplying a voltage signal of sinusoidal waveform to the upper electrode, and to control the ion energy of the plasma ions by supplying a bias voltage signal of non-sinusoidal waveform to the lower electrode. Accordingly, it may be possible to generate the plasma having an ion energy distribution shape of a single peak and it may be possible to control the plasma to have optimal ion incident energy for forming a carbon layer.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of some implementations and is not to be construed as limiting thereof. Although a few implementations have been described, those skilled in the art will readily appreciate that many modifications are possible in some implementations without materially departing from the novel teachings and advantages of the present disclosure. Accordingly, all such modifications are intended to be included within the scope of implementations, as defined in the claims.

1. A plasma deposition apparatus, comprising:
a process chamber;
a substrate stage in the process chamber, the substrate stage including an electrostatic chuck, a lower temperature maintenance portion, and a lower electrode, wherein the electrostatic chuck is configured to hold a substrate thereon with an electrostatic adsorption force, and the low temperature maintenance portion is configured to reduce a temperature of the substrate;
an exhaust portion including a vacuum pump that is configured to exhaust a gas inside the process chamber;
an upper electrode disposed on an upper portion of the process chamber facing the lower electrode;
a gas supply portion configured to supply a reaction gas including a hydrocarbon compound gas into the process chamber;
a first power supply configured to apply a source voltage of a sinusoidal waveform to the upper electrode to generate plasma; and
a second power supply configured to apply a bias voltage of a non-sinusoidal waveform to the lower electrode to control an ion energy of the plasma.

2. The plasma deposition apparatus of claim 1,
wherein the bias voltage has a voltage waveform that is repeated at a predetermined period, and
wherein the predetermined period includes:
a pulse period in which the bias voltage is applied having a fixed voltage level higher than a reference voltage level; and
a ramp period in which the bias voltage is applied having a variable voltage level that decreases at a constant slope from a first voltage level lower than the reference voltage level to a second voltage level lower than the first voltage level.

3. The plasma deposition apparatus of claim 2, wherein a length of the ramp period within the predetermined period is in a range of 40% to 80% of a length of the pulse period.

4. The plasma deposition apparatus of claim 2, wherein a voltage difference between the fixed voltage level of the pulse period and the first voltage level of the ramp period is 400 V or more.

5. The plasma deposition apparatus of claim 2, wherein a voltage difference between the first voltage level of the ramp period and the second voltage level of the ramp period is 100 V or more.

6. The plasma deposition apparatus of claim 1, wherein the ion energy of the plasma has an ion energy distribution of a single peak shape.

7. The plasma deposition apparatus of claim 1, wherein the exhaust portion is configured to maintain a pressure within the process chamber below 10 mTorr.

8. The plasma deposition apparatus of claim 1, wherein the low temperature maintenance portion is configured to maintain a temperature of the substrate within a range of −10° C. to 130° C.

9. The plasma deposition apparatus of claim 1, wherein an RF power of the source voltage of the sinusoidal waveform applied to the upper electrode by the first power supply is within a range of 50 W to 3,000 W.

10. The plasma deposition apparatus of claim 1, wherein the hydrocarbon compound gas includes at least one hydrocarbon compound selected from the group consisting of C₃H₆, C₄H₈, C₆H₁₂, and CH₄.

11. A plasma deposition apparatus, comprising:
a chamber configured to provide a space for processing a substrate;
a substrate stage within the chamber, the substrate stage being configured to support the substrate, and the substrate stage having a lower electrode;
an upper electrode disposed facing the lower electrode;
a first power supply having a sinusoidal power source configured to apply a sinusoidal voltage signal to the upper electrode to generate plasma within a plasma region of the chamber;
a second power supply configured to apply a non-sinusoidal voltage signal to the lower electrode to control an ion energy of the plasma;
a gas supply portion configured to supply a reaction gas into the plasma region of the chamber;
an exhaust portion having a vacuum pump that is configured to exhaust a gas within the process chamber; and
a substrate temperature adjustment portion configured to maintain a temperature of the substrate below a preset temperature,
wherein the reaction gas includes at least one hydrocarbon compound selected from the group consisting of C₃H₆, C₄H₈, C₆H₁₂, and CH₄ to deposit a carbon layer from the reaction gas.

12. The plasma deposition apparatus of claim 11,
wherein the non-sinusoidal voltage signal has a voltage waveform that is repeated at a predetermined period, and
wherein the predetermined period includes:
a pulse period where the non-sinusoidal voltage signal is applied having a fixed voltage level higher than a reference voltage level; and
a ramp period where the non-sinusoidal voltage signal is applied having a variable voltage level that decreases at a constant slope from a first voltage level lower than the reference voltage level to a second voltage level lower than the first voltage level.

13. The plasma deposition apparatus of claim 12, wherein a length of the ramp period within the predetermined period is in a range of 40% to 80% of a length of the pulse period.

14. The plasma deposition apparatus of claim 12, wherein a voltage difference between the fixed voltage level of the pulse period and the first voltage level of the ramp period is 400 V or more.

15. The plasma deposition apparatus of claim 11, wherein the exhaust portion is configured to maintain a pressure within the process chamber below 10 mTorr.

16. The plasma deposition apparatus of claim 11, wherein an RF power of the sinusoidal voltage signal applied to the upper electrode by the first power supply is within a range of 50 W to 3000 W.

17. The plasma deposition apparatus of claim 11, wherein the carbon layer has a carbon density of 2.0 g/cc or more.

18. The plasma deposition apparatus of claim 11, wherein the ion energy of the plasma has an ion energy distribution of a single peak shape.

19. The plasma deposition apparatus of claim 11, wherein the low temperature maintenance portion is configured to maintain a temperature of the substrate within a range of −10° C. to 130° C.

20. A plasma deposition apparatus comprising:
a chamber configured to provide a space for processing a substrate;
a substrate stage within the chamber, the substrate stage being configured to support the substrate, and the substrate stage having a lower electrode;
an upper electrode disposed facing the lower electrode;
a gas supply portion configured to supply a reaction gas including hydrocarbon compound gas into the chamber;
a first power supply having a sinusoidal power source that is configured to apply a sinusoidal voltage power to the upper electrode to generate plasma within the chamber;
a second power supply having a non-sinusoidal power source that is configured to apply a non-sinusoidal voltage power to the lower electrode to form a carbon layer on the substrate;
wherein the non-sinusoidal power has a voltage waveform that is repeated at a predetermined period, and
wherein the predetermined period includes:
a pulse period in which the non-sinusoidal power is applied having a fixed voltage level higher than a reference voltage level; and
a ramp period in which the non-sinusoidal power is applied having a variable voltage level that decreases at a constant slope from a first voltage level lower than the reference voltage level to a second voltage level lower than the first voltage level.

21. (canceled)
